(19) United States
(12) Patent Application Publication
(10) Pub. No.: US 2026/0259267 A1
(43) Pub. Date: Sep. 3, 2026

(54) METHOD AND DEVICE FOR TESTING AN SMC STATOR CORE

(71) Applicant: Schaeffler Technologies AG & Co. KG, Herzogenaurach (DE)

(72) Inventor: Andreas Lindner, Erlangen (DE)

(73) Assignee: Schaeffler Technologies AG & Co. KG, Herzogenaurach (DE)

(21) Appl. No.: 18/718,476

(22) PCT Filed: Oct. 20, 2022
(86) PCT No.: PCT/DE2022/100772

§ 371 Date: Jun. 11, 2024

(30) Foreign Application Priority Data
Dec. 16, 2021 (DE) 10 2021 133 457.8

(51) Int. Cl. G01R 31/34; H02K 1/14; H02K 1/2798; H02K 21/24

(52) U.S. Cl. CPC G01R 31/346; H02K 1/146; H02K 1/2798; H02K 21/24

(57) ABSTRACT

A method for testing an SMC stator core for an electric machine includes providing the SMC stator core to be tested and providing a plurality of windings in the form of printed circuits, The SMC stator core includes teeth and each printed circuit has cutouts which are adapted to the shape and arrangement of the teeth. The method also includes placing the printed circuits, which are stacked on top of one another, onto the teeth, covering the arrangement of the SMC stator core and the printed circuits with an iron return ring, which contacts the teeth, and operating the printed circuits as transformer windings while acquiring properties of the SMC stator core, which acts as a transformer core here. A device for testing the SMC stator core using the method is also disclosed.

### CROSS-REFERENCE TO RELATED APPLICATIONS

This application is the United States National Phase of PCT Appln. No. PCT/DE 2022/100772 filed Oct. 20, 2022, which claims priority to German Application No. DE 102021133457.8 filed Dec. 16, 2021, the entire disclosures of which are incorporated by reference herein.

### TECHNICAL FIELD

The present disclosure relates to a method for testing a stator core for an electric machine which is made of a soft magnetic composite material (SMC). The disclosure also relates to a device for testing such a stator core of an electric machine, e.g., an electric motor.

### BACKGROUND

An electric motor with a stator core made of an SMC material is known, for example, from EP 2 901 541 B1. The stator core of the known electric motor is formed in a pot-like manner, wherein tooth-like projections are arranged on the edge of the pot. The rotor of the electric motor according to EP 2 901 541 B1 has a multi-layer printed circuit board.

Further design options for stators and rotors of electric machines are described, for example, in the publications EP 1 598 920 B1, DE 10 2012 207 414 A1 and WO 2018/027330 A1. In principle, teeth of stators or rotors can be aligned either in the radial direction or in the axial direction of the electric machine concerned, as shown by way of example in these publications.

Powder-based materials are known to be an alternative to stator or rotor laminated cores in order to reduce eddy current losses compared to solid metallic, electrically conductive components and can be considered for a wide variety of geometric designs of electric motor components. Compared to standard electrical sheets, stator cores made of SMC materials typically exhibit hardly any eddy current losses due to their low electrical conductivity, but tend to have more core losses, i.e., hysteresis losses.

With regard to a ferromagnetic powder which is suitable for the production of components of electric motors or transformers, reference is made by way of example to the publication U.S. Pat. No. 9,640,306 B2. In this case, soft magnetic particles are surrounded by various layers, including an inorganic insulating layer based on phosphorus.

As a rule, soft magnetic powder-based composite materials intended for use in electric machines have largely isotropic material properties when it comes to their magnetic characteristics. Deviating from this, a soft magnetic composite material described in WO 2016/020077 A1, for example, has a high anisotropy of permeability.

The toroidal core measurement method is particularly suitable for determining the material characteristics of soft magnetic materials. In this context, reference is made to the following dissertation:
Alexander Stadler: Messtechnische Bestimmung und Simulation der Kernverluste in weichmagnetischen Materialien (Measurement and simulation of core losses in soft magnetic materials), Technische Fakultät der Universität Erlangen-Nürnberg, Erlangen 2009
   In this dissertation, a series connection of multiple identical toroidal cores is proposed. The resulting averaging effect is intended to reduce scattering within a batch.

### SUMMARY

The present disclosure is based on the object of achieving progress in the testing of SMC stator cores compared to the prior art, wherein rational testing should also be possible as part of the series production of electric motors or generators.

The method by which a stator core made of a soft magnetic composite material can be tested comprises the following steps:
providing a plurality of windings in the form of printed circuits, each of which has cutouts which are adapted to the shape and arrangement of teeth of an SMC stator core to be tested,
placing the printed circuits, which are stacked on top of one another, onto the teeth of the SMC stator core,
covering the arrangement of the SMC stator core and the printed circuits with an iron return ring, which contacts the teeth, and
operating the printed circuits as transformer windings while acquiring properties of the SMC stator core, which acts as a transformer core here.

The present disclosure is based on the idea that soft magnetic powder-based materials can be tested in principle by forming a special test object from the soft magnetic material. The properties of the test object can then be determined using the toroidal core measurement method, for example. The disadvantage here is the high cost of sample preparation and the fact that the geometry of the test object does not correspond to the geometry of the component intended for use in an electric machine.

In principle, these disadvantages are not present in the test method according to the application, which uses the SMC stator core in its final form intended for installation in an electric machine during the test. Another advantage is the use of prefabricated printed circuits, which eliminate the need to wrap a sample and are available for testing practically any number of stator cores in succession, even semi-automatically.

The printed circuits to be stacked on top of one another, which are to be placed on the SMC stator core for the purpose of testing, can be positioned either manually or robotically. The same applies to the iron return ring. In each case, a test setup is produced which is intended for testing according to the transformer principle. In addition, it is also possible to carry out a heating measurement.

According to one possible embodiment of the test method, primary and secondary windings, which are each in the form of printed circuits, are placed onto the SMC stator core in an alternating manner. For example, a total of eight or more printed circuits, i.e., at least four primary windings and at least four secondary windings, are stacked on top of one another. Within the transformer produced in this way and completed by the iron return ring, the magnetic circuit is closed by the ring-shaped stator core to be tested, among others. During the test, a time-varying current is impressed in the sense of a current control, which causes a magnetic flux in the stator core. The magnetic flux in turn induces an electrical voltage in the secondary winding that can be measured in an easy and reliable manner.

Corresponding to the basic shape of the SMC stator cores to be tested, the printed circuits, for example, have a ring shape with cutouts distributed uniformly around the circumference for one tooth of the stator core in each case. In this regard, it is assumed that the teeth extend in the axial direction of the electric machine. The thickness of the printed circuits depends on the height of the teeth of the SMC stator core and the number of printed circuits that are to be stacked on top of one another within a measuring arrangement. For different SMC stator cores to be tested with different dimensions, in particular different diameters, differently dimensioned printed circuits can accordingly be provided, wherein a standardized measuring and evaluation device can be used for carrying out and evaluating the measurements with which the magnetic properties are determined.

In contrast with the SMC stator core, which is later used in the series production of electric machines, the iron return ring is exclusively a component of the testing device. In principle, the iron return ring can be a solid metal component or a component made of electrical sheet. In the latter case, a structure of the iron return ring including concentric rings is advantageous with regard to the magnetic flux, but this is demanding in terms of production engineering. A simpler production method, but less favorable in terms of magnetic flux and occurring eddy currents, is to build the iron return ring from annular disc-shaped sheets stacked on top of one another.

Particularly in the case of frequencies in the kHz range, it is advantageous to produce the iron return ring from a soft magnetic powder-based composite material. In an example embodiment, this is the same SMC material from which the stator cores to be tested are made.

Overall, the testing device is particularly suitable for the incoming goods inspection of an industrial production line in which SMC stator cores are inserted into the testing device in a fully automatic manner and measured magnetically. Any rejects relating to the stator cores are therefore detected right at the start of production.

The electric motors to be produced, the stator cores of which are 100% tested using the test method according to the application, are, for example, permanent-magnet motors. The motors may be used in cobots, for example. In this context, reference is made by way of example to the publications EP 3 643 455 A1 and US 2021/0114239 A1.

### BRIEF DESCRIPTION OF THE DRAWINGS

In the following, an exemplary embodiment is explained in more detail with reference to drawings. In the purely schematic figures:

FIG. 1 shows a device for testing an SMC stator core of an electric machine,

FIG. 2 shows the stator core of the arrangement according to FIG. 1,

FIG. 3 shows an iron return ring placed on the stator core within the arrangement according to FIG. 1,

FIG. 4 shows one of multiple printed circuits used in the arrangement according to FIG. 1, and

FIG. 5 shows an exploded view of an electric motor comprising two stator cores.

### DETAILED DESCRIPTION

A testing device designated overall with the reference sign 1 is used to test stator cores 2, which are installed in electric motors 10. Each stator core 2 describes a crown shape with a ring section 4 and numerous teeth 3 adjoining it and aligned in the axial direction of the ring section 4. The stator cores 2 are made of a soft magnetic composite material, i.e., SMC material.

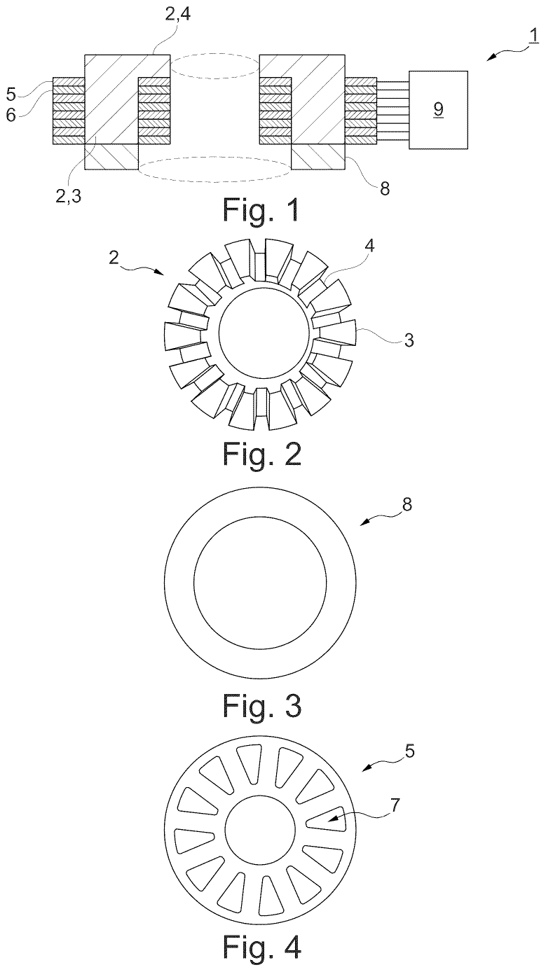

The stator cores 2 are tested using annular disc-shaped printed circuits 5, 6. Each printed circuit 5, 6 has cutouts 7 whose shape and arrangement correspond to the cross-sectional shape of the teeth 3. Within the testing device 1, the printed circuits 5, 6 are placed on the teeth 3 of the stator core 2 in a stacked manner. An iron return ring 8 is then placed on the end faces of the teeth 3, resulting in the arrangement outlined in FIG. 1. As indicated in FIG. 1, the printed circuits 5, 6 are connected to an evaluation unit 9 in such a way that a printed circuit 5 as a primary winding and a printed circuit 6 as a secondary winding form the stack of printed circuits 5, 6 in an alternating manner.

Primary windings 5 are energized during the test. The electrical voltage induced in the secondary windings 6 is measured by means of the evaluation unit 9. Once the tests have been completed, the stator core 2 is removed from the testing device 1 again. The stator core 2, i.e., the SMC stator core, can then be installed as a component of an electric motor 10, assuming a positive result of the test of its magnetic properties.

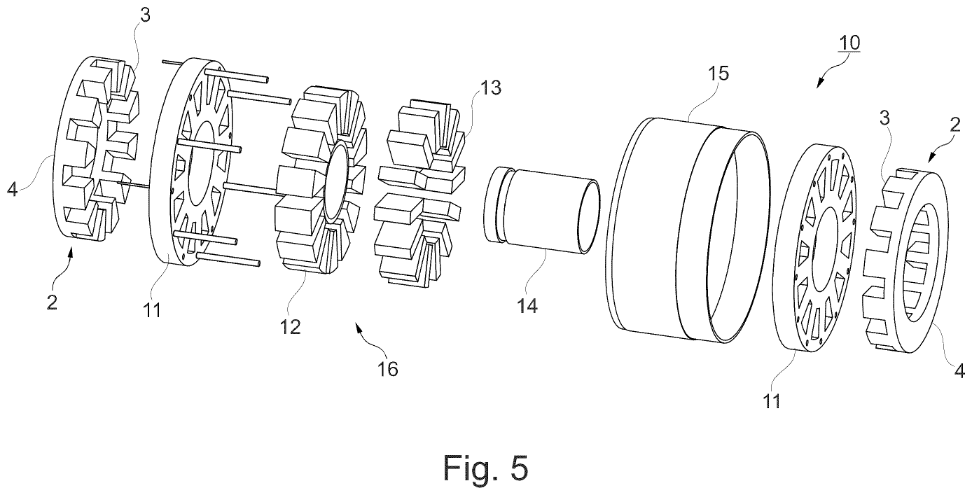

The electric motor 10, the structure of which is illustrated in FIG. 5, is a brushless permanent-magnet motor. As an electric machine, the electric motor 10 has stator cores 2 arranged on its two end faces in a mirrored manner, the teeth 3 of which are directed towards one another. The teeth 3 of each stator core 2 engage in a printed circuit board arrangement 11, the basic shape of which corresponds to the shape of the printed circuits 5, 6 used for testing purposes. The rotor of the electric motor 10, designated overall with the reference sign 16, includes a laminated rotor core 12 made of SMC material, into which cuboid permanent magnets 13 are inserted. The rotor 16 is firmly connected to a shaft 14 of the electric motor 10. The housing of the electric motor 10 is designated with the reference sign 15. Means known per se for mounting the shaft 14 are not shown in FIG. 5.

### REFERENCE NUMERALS

1 Testing device
2 Stator core
3 Tooth
4 Ring section
5 Primary winding, printed circuit
6 Secondary winding, printed circuit
7 Cutout
8 Iron return ring
9 Evaluation unit
10 Electric motor, electric machine
11 Printed circuit board arrangement
12 Laminated rotor core
13 Permanent magnet
14 Shaft
15 Housing
16 Rotor

1. A method for testing an SMC stator core for an electric machine, comprising the following steps:
providing the SMC stator core to be tested, the SMC stator core comprising teeth,
providing a plurality of windings in the form of printed circuits, each of which has cutouts which are adapted to the shape and arrangement of the teeth,
placing the printed circuits, which are stacked on top of one another, onto the teeth,
covering the arrangement of the SMC stator core and the printed circuits with an iron return ring, which contacts the teeth,
operating the printed circuits as transformer windings while acquiring properties of the SMC stator core, which acts as a transformer core here.

2. The method according to claim 1, wherein:
the printed circuits are divided into primary windings and secondary windings, and
the primary windings and the secondary windings are placed onto the SMC stator core in an alternating manner.

3. The method according to claim 2, wherein a total of at least eight printed circuits are stacked on top of one another.

4. The method according to claim 1, wherein the SMC stator core, the printed circuits and the iron return ring are assembled robotically.

5. A device for testing an SMC stator core for an electric machine using the method of claim 1, comprising:
the plurality of windings in the form of printed circuits, each of which has cutouts which are adapted to the shape and arrangement of the teeth,
the iron return ring, and
an evaluation unit arranged for electrical connection to the windings to acquire the properties of the SMC stator core.

6. The device according to claim 5, wherein the printed circuits each have a ring shape with cutouts distributed uniformly around the circumference.

7. The device according to claim 5, wherein the printed circuits each have a thickness corresponding to not more than one eighth of a height of the teeth of the SMC stator core

8. The device according to claim 5, wherein the iron return ring is made of a soft magnetic composite (SMC) material.
